(19) United States
(12) Patent Application Publication
(10) Pub. No.: US 2023/0126073 A1
(43) Pub. Date: Apr. 27, 2023

(54) DISPLAY DEVICE

(71) Applicant: Samsung Display Co., LTD., Yongin-si (KR)

(72) Inventors: Joon Gu LEE, Seoul (KR); HYE JIN GWARK, Suwon-si (KR); ARONG KIM, Hwaseong-si (KR); Jae Ik KIM, Seoul (KR); JUNGSUN PARK, Yongin-si (KR); HEEMIN PARK, Hwaseong-si (KR); Yeon Hwa LEE, Hwaseong-si (KR); KYU H. HWANG, Seongnam-si (KR)

(21) Appl. No.: 17/930,967

(22) Filed: Sep. 9, 2022

(30) Foreign Application Priority Data
Oct. 27, 2021 (KR) 10-2021-0144457

(51) Int. Cl. H01L 33/38; H01L 33/62; H01L 33/20; H01L 33/00

(52) U.S. Cl. CPC H01L 33/382; H01L 33/62; H01L 33/20; H01L 33/005; H01L 2933/0016; H01L 2933/0066

(57) ABSTRACT

A display device and a manufacturing method of a display device are provided. A display device includes: a substrate; a semiconductor layer on the substrate; a source electrode and a drain electrode on the semiconductor layer; an auxiliary electrode on a same layer as the source electrode and the drain electrode; a first electrode electrically connected with the source electrode or the drain electrode; a light emitting element layer on the first electrode; and a second electrode on the light emitting element layer, and the auxiliary electrode includes at least one groove located inside the auxiliary electrode.

### CROSS-REFERENCE TO RELATED APPLICATION

This application claims priority to and the benefit of Korean Patent Application No. 10-2021-0144457, filed on Oct. 27, 2021 in the Korean Intellectual Property Office, the entire content of which is incorporated herein by reference.

### BACKGROUND

### 1. Field

Aspects of embodiments of the present disclosure relate to a display device and a manufacturing method of a display device.

### 2. Description of the Related Art

The importance of display devices is gradually increasing with the development of multimedia. In response to this, various display devices, such as a liquid crystal display (LCD) and a light emitting diode (OLED) display, have been developed.

Among the display devices, a light emitting display device includes a light emitting element that is a self-luminous element. The light emitting element may include two opposing electrodes and an emission layer interposed therebetween. Electrons and holes provided from the two electrodes are recombined in the emission layer to generate excitons, and the generated excitons change from an exited state to a ground state such that light can be emitted.

Since such a light emitting display device does not require a separate light source, it has low power consumption and can be configured in a light and thin shape, as well as to have high quality characteristics, such as a wide viewing angle, high luminance and contrast, and fast response speed, and thus attracts attention as a next generation display device.

The above information disclosed in this Background section is only for enhancement of understanding of the background of the invention, and, therefore, it may contain information that does not form the prior art that is already known in this country to a person of ordinary skill in the art.

### SUMMARY

According to an aspect of embodiments of the present disclosure, a display device capable of minimizing or reducing voltage drop is provided.

A display device according to one or more embodiments includes: a substrate; a semiconductor layer on the substrate; a source electrode and a drain electrode on the semiconductor layer; an auxiliary electrode on a same layer as the source electrode and the drain electrode; a first electrode electrically connected with the source electrode or the drain electrode; a light emitting element layer on the first electrode; and a second electrode on the light emitting element layer, wherein the auxiliary electrode includes at least one groove located inside the auxiliary electrode.

The light emitting element layer and the second electrode may be located in the groove of the auxiliary electrode, and the second electrode may directly contact a side surface of the second electrode in the groove of the auxiliary electrode.

The auxiliary electrode may have an undercut structure in which a side surface is positioned inside a top surface, the light emitting element layer may be in direct contact with the auxiliary electrode on the side surface of the auxiliary electrode, and a part of the second electrode and the auxiliary electrode directly may contact on the side surface of the auxiliary electrode.

A region where the second electrode and the auxiliary electrode directly contact may be farther from the substrate than a region where the light emitting element layer and the auxiliary electrode directly contact.

The auxiliary electrode may include a first layer, a second layer, and a third layer, and a planar area of the second layer may be narrower than planar areas of the first layer and the third layer.

A width of a groove of the at least one groove of the auxiliary electrode may be wider than the thickness of the auxiliary electrode.

A width of a groove of the at least one groove of the auxiliary electrode may be 1,000 Å to 20,000 Å.

A planar shape of the auxiliary electrode may be polygonal or circular.

A planar shape of a groove of the at least one groove may be linear, polygonal, or circular.

A planar shape of the auxiliary electrode and a planar shape of a groove of the at least one groove may be the same.

A display device according to one or more embodiments includes: a substrate; a semiconductor layer on the substrate; a source electrode and a drain electrode on the semiconductor layer; a first electrode electrically connected with the source electrode or the drain electrode; a light emitting element layer on the first electrode; a second electrode on the light emitting element layer; and an auxiliary electrode on a same layer as the first electrode, wherein the auxiliary electrode includes at least one groove located inside the auxiliary electrode.

The light emitting element layer and the second electrode may be located in the groove of the auxiliary electrode, and the second electrode may directly contact a side surface of the auxiliary electrode in the groove of the auxiliary electrode.

The auxiliary electrode may have an undercut structure in which a side surface is positioned inside a top surface, the light emitting element layer may be in direct contact with the auxiliary electrode on the side surface of the auxiliary electrode, and a part of the second electrode ad the auxiliary electrode may directly contact the side surface of the auxiliary electrode.

A region where the second electrode and the auxiliary electrode directly contact may be farther from the substrate than a region where the light emitting element layer and the auxiliary electrode directly contact.

A width of a groove of the at least one groove of the auxiliary electrode may be wider than a thickness of the auxiliary electrode.

A width of a groove of the at least one groove of the auxiliary electrode may be 1,000 Å to 20,000 Å.

A planar shape of the auxiliary electrode may be polygonal or circular.

A planar shape of a groove of the at least one groove may be linear, polygonal, or circular.

A planar shape of the auxiliary electrode and a planar shape of a groove of the at least one groove may be the same.

A manufacturing method of a display device according to one or more embodiments includes: forming a semiconductor layer on a substrate; forming a source electrode and a drain electrode that are electrically connected with the semiconductor layer; forming a first electrode that is electrically connected with the source electrode or the drain electrode; and forming an auxiliary electrode on a same layer as the source electrode and the drain electrode or on a same layer as the first electrode, wherein the auxiliary electrode includes one or more grooves.

The manufacturing method of the display device may further include forming a light emitting element layer on the first electrode, wherein the light emitting element layer may be deposited at a first angle with respect to a top surface of the auxiliary electrode.

The manufacturing method of the display device may further include forming a second electrode on the light emitting element layer, wherein the second electrode may be deposited at a second angle with respect to the top surface of the auxiliary electrode, and the second angle may be smaller than the first angle.

In the forming of the second electrode on the light emitting element layer, the second electrode may directly contact the auxiliary electrode at a side surface of the auxiliary electrode.

A region in which the second electrode and the auxiliary electrode directly contact may be located farther from the substrate than a region in which the light emitting device layer and the auxiliary electrode directly contact each other.

The manufacturing method of the display device may further include etching the auxiliary electrode to form an undercut structure in which a side surface of the auxiliary electrode is located more inward than a top surface of the auxiliary electrode.

According to an aspect of embodiments, a display device capable of minimizing or reducing voltage drop is provided.

### BRIEF DESCRIPTION OF THE DRAWINGS

FIG. 1 schematically illustrates a display device according to an embodiment.

FIG. 2 is a cross-sectional view of the display device of FIG. 1, taken along the line II-II′.

FIG. 3 illustrates a top surface of an auxiliary electrode according to an embodiment.

FIG. 4 is a cross-sectional view of the auxiliary electrode of FIG. 3, taken along the line IV-IV′.

FIG. 5 shows a configuration of deposition of a light emitting element layer in an auxiliary electrode according to an embodiment.

FIG. 6 shows a configuration of deposition of a second electrode in an auxiliary electrode according to an embodiment.

FIG. 7 to FIG. 9 illustrate a process in which an auxiliary electrode and a second electrode are in contact at a top surface of the auxiliary electrode.

FIG. 10 shows a top surface of an auxiliary electrode in which a groove is not formed therein; and FIG. 11 illustrates a cross-section of the auxiliary electrode of FIG. 10, taken along the line X-X′.

FIG. 12 illustrates a top surface of an auxiliary electrode including an inner groove; and FIG. 13 illustrates a cross-section of the auxiliary electrode of FIG. 12, taken along the line XII-XII′.

FIG. 14 shows a part of the cross-section of the auxiliary electrode of FIG. 13, illustrating an undercut portion.

FIG. 15 illustrates a cross-section corresponding to that of FIG. 4, according to another embodiment.

FIG. 16 illustrates a cross-section corresponding to that of FIG. 2, according to another embodiment.

FIG. 17 to FIG. 31 illustrate shapes of auxiliary electrodes according to various embodiments.

DESCRIPTION OF REFERENCE SYMBOLS

| | | | |
|---|---|---|---|
| SUB: | substrate | ACT: | semiconductor layer |
| AE: | auxiliary electrode | SE: | source electrode |
| DE: | drain electrode | 191: | first electrode |
| 270: | second electrode | 360: | light emitting element layer |
| DPA: | display area | NDA: | non-display area |

| | |
|---|---|
| ED: | light emitting element |

### DETAILED DESCRIPTION

The present invention will be described more fully herein with reference to the accompanying drawings, in which some embodiments of the invention are shown. As those skilled in the art would realize, the described embodiments may be modified in various different ways.

The drawings and description are to be regarded as illustrative in nature and not restrictive. Like reference numerals designate like elements throughout the specification.

In addition, since the size and thickness of each configuration shown in the drawings may be arbitrarily indicated for better understanding and ease of description, the present invention is not necessarily limited to the drawings. In the drawings, the thickness of layers, films, panels, regions, etc., may be exaggerated for clarity. In addition, in the drawings, the thickness of some layers and regions may be exaggerated for better understanding and ease of description.

It is to be understood that when an element such as a layer, film, region, or substrate is referred to as being “on” another element, it may be directly on the other element or one or more intervening elements may also be present. In contrast, when an element is referred to as being “directly on” another element, there are no intervening elements present. Further, throughout the specification, the word “on” a target element is to be understood to mean positioned above or below the target element, and is not necessarily to be understood to mean positioned “at an upper side” based on a direction opposite to gravity.

In addition, unless explicitly described to the contrary, the word “comprise,” and variations such as “comprises” or “comprising,” are to be understood to imply the inclusion of stated elements but not the exclusion of any other elements.

Further, throughout the specification, the phrase “on a plane” means viewing a target portion from the top, and the phrase “on a cross-section” means viewing a cross-section formed by vertically cutting a target portion from the side.

Unless otherwise defined, all terms (including technical and scientific terms) used herein have the same meaning as terms commonly understood by those skilled in the art to which this invention belongs. Also, terms such as terms defined in commonly used dictionaries should be interpreted as having meaning consistent with meaning in the context of the related art, and unless the term is interpreted in an ideal or overly formal sense, they are explicitly defined here.

Herein, a display device according to an embodiment will be described with reference to the accompanying drawings.

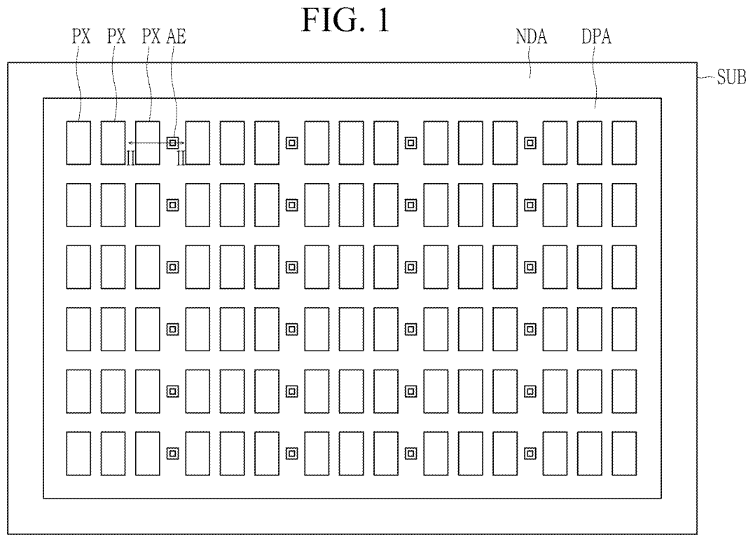

FIG. 1 schematically illustrates a display device according to an embodiment. Referring to FIG. 1, a display device according to an embodiment includes a display area DPA and a non-display area NDA.

A plurality of pixels PX may be positioned in the display area DPA of a substrate SUB. Each pixel PX may include a light emitting element and thus may emit light. Referring to FIG. 1, an auxiliary electrode AE may be positioned between pixels PX of the plurality of pixels PX. The auxiliary electrode AE may improve luminance uniformity of the pixel PX by minimizing or reducing a voltage drop (IR drop) caused by high electrical resistance of a second electrode 270, which will be described later. That is, in the substrate SUB (e.g., a large-scaled substrate), a luminance non-uniformity phenomenon may occur due to voltage drop. In an embodiment, the auxiliary electrode AE is connected to the second electrode 270 to reduce the resistance of the second electrode 270 and minimize or reduce the voltage drop.

FIG. 1 illustrates a configuration in which the auxiliary electrode AE is positioned as one for each three pixels PX, but this is only provided as an example, and the number and position of the auxiliary electrode AE may vary. For example, the auxiliary electrode AE may be positioned one for every twenty pixels PX.

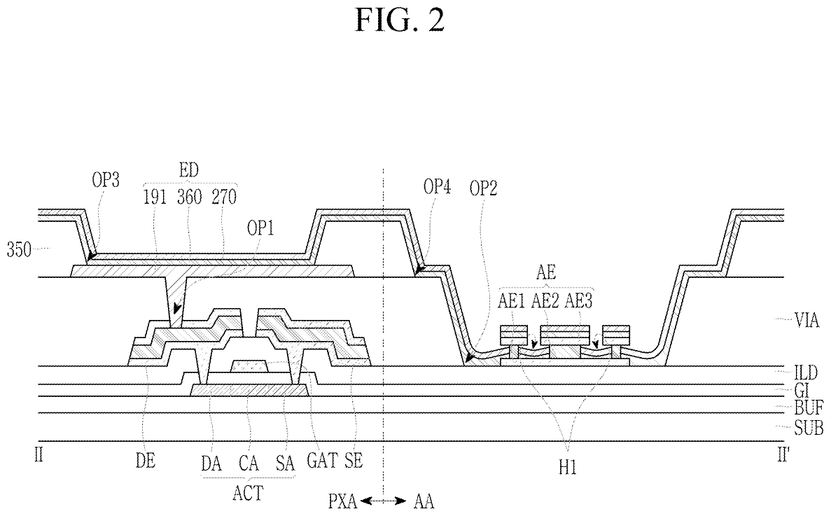

FIG. 2 is a cross-sectional view of the display device of FIG. 1, taken along the line II-II′. Herein, a connection form of the auxiliary electrode AE and the second electrode 270 will be mainly described.

FIG. 2 illustrates a pixel area PXA where light is emitted and an auxiliary electrode area AA positioned between pixel areas PXA. The pixel area PXA is a region where light is emitted by a light emitting element.

Referring to FIG. 2, a buffer layer BUF may be positioned on the substrate SUB. The substrate SUB may be formed of various materials, such as a glass material, a metallic material, or a plastic material including any of polyethylene terephthalate (PET), polyethylene naphthalate (PEN), and polyimide.

The buffer layer BUF may include any of a silicon oxide (SiOₓ), a silicon nitride (SiNₓ), a silicon oxynitride (SiOₓN_{y}), and amorphous silicon (Si). The buffer layer BUF forms a smooth surface on an upper portion of the substrate SUB and blocks the penetration of impurity elements. However, the buffer layer BUF may be omitted depending on an embodiment.

A semiconductor layer ACT is positioned on the buffer layer BUF. The semiconductor layer ACT includes a channel area CA, and a source area SA and a drain area DA that are positioned at opposite sides of the channel area CA. The source area SA and the drain area DA are in a state of having conductivity by doping or plasma treatment. The semiconductor layer ACT may include amorphous silicon, crystalline silicon, or an oxide semiconductor.

A gate insulating layer GI is positioned on the semiconductor layer ACT.

The gate insulating layer GI may include any of a silicon oxide (SiOₓ), a silicon nitride (SiNₓ), and a silicon oxynitride (SiOₓN_{y}), and may be a single-layer or multi-layer structure thereof.

A gate electrode GAT is positioned on the gate insulating layer GI. The gate electrode GAT may include molybdenum (Mo), aluminum (AI), copper (Cu) and/or titanium (Ti), and may be a single-layer or multi-layer structure thereof.

An interlayer insulating layer ILD may be positioned on the gate electrode GAT. The interlayer insulating layer ILD may include any of a silicon oxide (SiOₓ), a silicon nitride (SiNₓ), and a silicon oxynitride (SiOₓN_{y}), and may be a single-layer or multi-layer structure thereof.

In an embodiment in which the interlayer insulating layer ILD is a double layer, the silicon oxide layer may be a lower layer, and the silicon nitride may be an upper layer.

A source electrode SE and a drain electrode DE may be positioned on the interlayer insulating layer ILD. The source electrode SE and the drain electrode DE respectively contact the source area SA and the drain area DA of the semiconductor layer ACT through an opening of the interlayer insulating layer ILD.

In an embodiment, the auxiliary electrode AE is positioned on a same layer as the source electrode SE and the drain electrode DE. In an embodiment, the source electrode SE, the drain electrode DE, and the auxiliary electrode AE may be formed by a same process and contain a same material. For example, the source electrode SE, the drain electrode DE, and the auxiliary electrode AE may include aluminum (AI), platinum (Pt), palladium (Pd), silver (Ag), magnesium (Mg), gold (Au), nickel (Ni), neodymium (Nd), iridium (Ir), chromium (Cr), nickel (Ni), calcium (Ca), molybdenum (Mo), titanium (Ti), tungsten (W), and/or copper (Cu), and the like, and may be a single-layer or multi-layer structure thereof. For example, the source electrode SE, the drain electrode DE, and the auxiliary electrode AE may have a triple-layered structure of a first layer containing a refractory metal, such as molybdenum, chromium, tantalum, and titanium, or an alloy thereof, a second layer containing an aluminum-based metal with low resistivity, a silver-based metal, a copper-based metal, and a third layer containing a refractory metal, such as molybdenum, chromium, tantalum, and titanium.

FIG. 2 illustrates a configuration in which the source electrode SE, the drain electrode DE, and the auxiliary electrode AE have a triple-layered structure. Referring to FIG. 2, a second layer AE2 of the auxiliary electrode AE may have an undercut structure that is etched into a first layer AE1 and a third layer AE3. Although this will be described in further detail later, since the auxiliary electrode AE has an undercut structure, it may be in contact with the second electrode 270 from the side.

In FIG. 2, the auxiliary electrode AE is illustrated to have a triple-layered structure, but this is just an example, and the auxiliary electrode AE may be formed of a single layer or may have a dual-layer structure. In another embodiment, it may have a quadruple layer or more laminated structure. In this case, also, the auxiliary electrode AE may have an undercut structure.

In addition, referring to FIG. 2, the auxiliary electrode AE includes a groove H1 formed thereinside. As shown in FIG. 2, the inside of the groove H1 may also have an undercut structure. Since the auxiliary electrode AE includes the groove H1, although it will be described separately later, a contact area between the auxiliary electrode AE and the second electrode 270 can be increased. The contact form of the auxiliary electrode AE and the second electrode 270 will be described in further detail later with reference to another drawing.

An insulating layer VIA is positioned on the source electrode SE, the drain electrode DE, and the auxiliary electrode AE. The insulating layer VIA may include an organic insulation material, such as a general-purpose polymer such as any of polymethyl methacrylate (PMMA) or polystyrene (PS), polymer derivatives with phenolic groups, acryl-based polymers, imide-based polymers, polyimides, acryl-based polymers, siloxane-based polymers, and the like.

The insulating layer VIA may include a first opening OP1 overlapping the drain electrode DE, and a second opening OP2 overlapping the auxiliary electrode AE.

The first electrode 191 is formed on the insulating layer VIA and is connected with the drain electrode DE through the first opening OP1 of the insulating layer VIA. In an embodiment, the first electrode 191 may include one or more of Ag, Mg, Al, Pt, Pd, Au, Ni, Nd, Ir, Cr, ITO, IZO, ZnO, and/or In₂O₃.

The first electrode 191 may be a reflective electrode, and may include a reflective film formed of Ag, Mg, Al, Pt, Pd, Au, Ni, Nd, Ir, Cr, or a compound thereof, and a film positioned on the reflective film and formed of ITO, IZO, ZnO, or In₂O₃.

A partitioning wall 350 may be positioned on the first electrode 191.

The partitioning wall 350 may include an organic insulation material, such as a general-purpose polymer such as any of polymethyl methacrylate (PMMA) or polystyrene (PS), polymer derivatives with phenolic groups, acryl-based polymers, imide-based polymers, polyimides, acryl-based polymers, siloxane-based polymers, and the like.

The partitioning wall 350 may include a third opening OP3 overlapping the first electrode 191 and a fourth opening OP4 overlapping the auxiliary electrode AE. Although the fourth opening OP4 is illustrated to be wider than the second opening OP2, depending on embodiments, the second opening OP2 and the fourth opening OP4 may be formed concurrently through a same process. In this case, a side surface of the second opening OP2 and a side surface of the fourth opening OP4 may be connected to, or define, a single plane.

A light emitting element layer 360 may be positioned in the third opening OP3 of the partitioning wall 350. In an embodiment, the light emitting element layer 360 may include an electron injection layer, an electron transport layer, an emission layer, a hole transport layer, and a hole injection layer. The light emitting element layer 360 may be formed on side and top surfaces of the auxiliary electrode AE having an undercut structure.

The second electrode 270 may be positioned on the partitioning wall 350 and the light emitting element layer 360. The first electrode 191, the light emitting element layer 360, and the second electrode 270 may form a light emitting diode ED. The second electrode 270 may be formed on side and top surfaces of the auxiliary electrode AE, and may be deposited at a different angle from the light emitting element layer 360 to directly contact the auxiliary electrode AE.

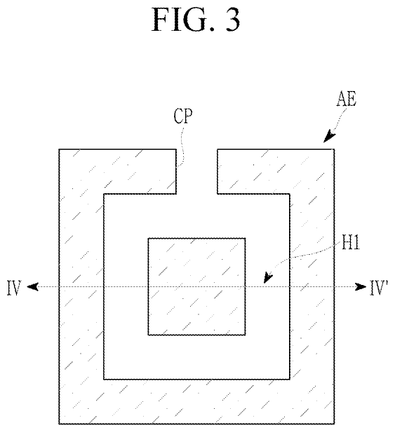

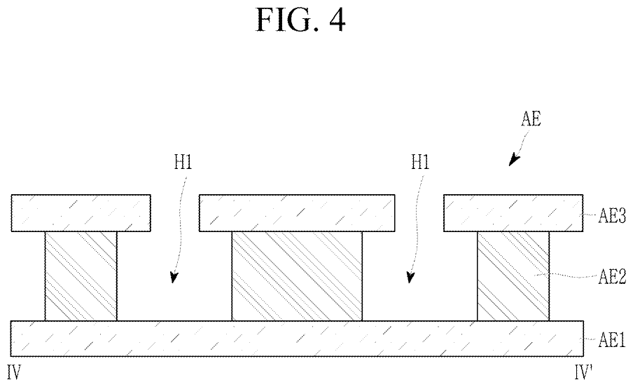

Herein, the contact with the second electrode 270 in the auxiliary electrode AE will be described. FIG. 3 illustrates a top surface of the auxiliary electrode AE according to an embodiment. FIG. 4 is a cross-sectional view of the auxiliary electrode AE of FIG. 3, taken along the line IV-IV′.

Referring to FIG. 3 and FIG. 4, the auxiliary electrode AE according to an embodiment includes a first layer AE1, a second layer AE2, and a third layer AE3, and a part of the second layer AE2 is etched such that the auxiliary electrode AE has an undercut structure. That is, the first layer AE1 and the third layer AE3 protrude more than the second layer AE2. In addition, first grooves H1 having the same shape as the auxiliary electrode AE are formed inside the auxiliary electrode AE.

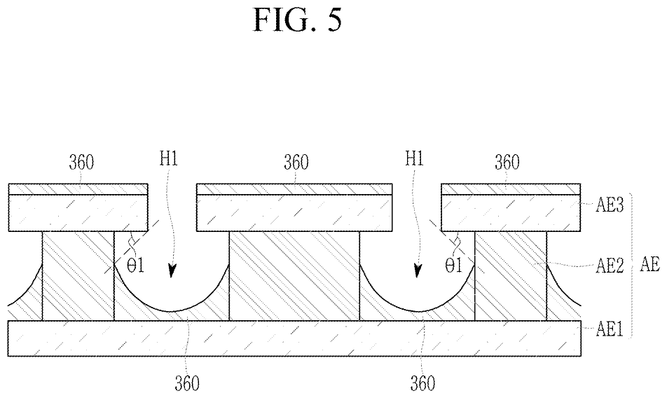

Referring to FIG. 3, the auxiliary electrode AE according to an embodiment may include a cut-off portion CP formed in the third layer AE3 of the auxiliary electrode AE. That is, as shown in FIG. 3, a planar shape of the auxiliary electrode AE has a structure including portions that are spaced apart from each other at the cut-off portion CP. The cut-off portion CP may be a region where the second electrode 270, which is in contact with the auxiliary electrode AE from the inside of the groove H1, and the second electrode 270, which is in contact with the auxiliary electrode AE from the outside of the groove H1, are connected with each other. FIG. 5 shows a configuration of deposition of the light emitting element layer 360 in the auxiliary electrode AE according to an embodiment. The light emitting element layer 360 may be deposited at a first angle θ1 with respect to the third layer AE3. In an embodiment, the first angle θ1 may be 40 degrees to 50 degrees.

Thus, as shown in FIG. 5, the light emitting element layer 360 may not be deposited to a portion of a side surface of the second electrode AE2 of the auxiliary electrode AE. This is because a deposition material cannot reach a partial region according to a deposition angle of the light emitting element layer 360, as shown in FIG. 5.

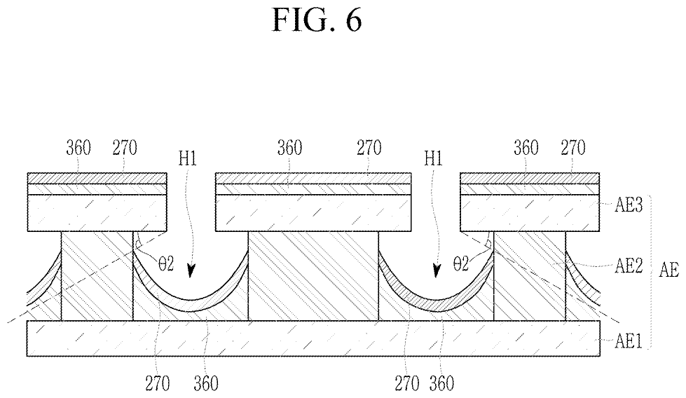

Next, as shown in FIG. 6, the second electrode 270 is deposited at a second angle θ2. In this case, the second angle θ2 may be smaller than the first angle θ1. That is, when referring to a back plane of the third layer AE3 of the auxiliary electrode AE, the second angle θ2 at which the second electrode 270 is deposited may be smaller than the first angle θ1 at which the light emitting element layer 360 is deposited. In an embodiment, the second angle θ2 may be 30 degrees to 40 degrees.

Thus, as shown in FIG. 6, the second electrode 270 may be deposited to a region where the light emitting element layer 360 cannot be deposited. Therefore, the second electrode 270 and auxiliary electrode AE may be in direct contact. As shown in FIG. 6, the second electrode 270 and a side of the second layer AE2 of the auxiliary electrode AE may be in direct contact.

A method that enables the second electrode 270 to contact the auxiliary electrode AE at the side is economical because there is no need of removing the light emitting element layer 360 for contact between the second electrode 270 and the auxiliary electrode AE.

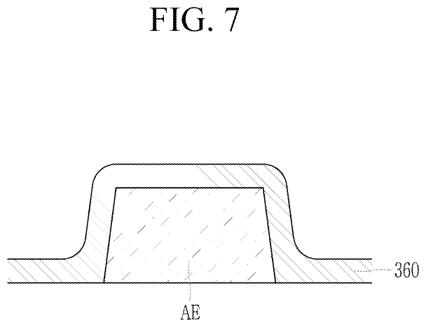

FIG. 7 to FIG. 9 illustrate a process in which the auxiliary electrode AE and the second electrode 270 are in contact at a top surface of the auxiliary electrode AE.

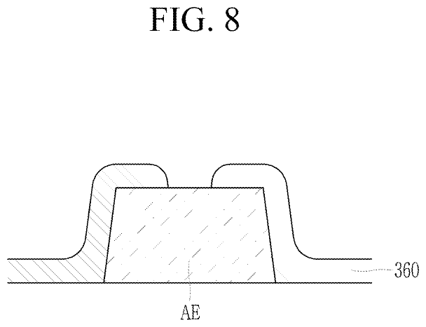

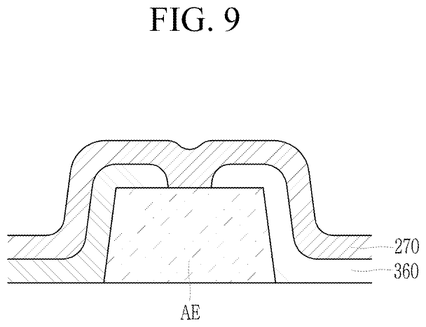

Referring to FIG. 7, the light emitting element layer 360 formed in the previous stage is positioned over the auxiliary electrode AE. For such a contact, as shown in FIG. 8, some of the light emitting element layer 360 is removed. Next, as shown in FIG. 9, the second electrode 270 is formed and then the second electrode 270 and the auxiliary electrode AE contact each other.

That is, in this case, a process for removing the light emitting element layer is additionally required compared to the embodiment of FIG. 5 and FIG. 6. This is undesirable because it increases the time required for the process.

However, in the display device according to an embodiment, the auxiliary electrode AE is formed in an undercut structure, and incident angles of the light emitting element layer 360 and the second electrode 270 are different on the side, and, thus, the second electrode 270 and auxiliary electrode AE directly contact each other at the sides of the second electrode 270 and the auxiliary electrode AE. This is economical since the removal process of the light emitting element layer 360 is not required.

However, when the auxiliary electrode AE and the second electrode 270 are in contact from the side, the contact area may be reduced compared to the top contact. However, in the display device according to an embodiment, a groove is formed inside the auxiliary electrode AE, and the contact area between the auxiliary electrode AE and the second electrode 270 is increased, even on the side of the inner groove. That is, the side area is increased by forming the internal groove in the auxiliary electrode AE, and the contact area of the second electrode 270 is maximized or increased through the side surfaces.

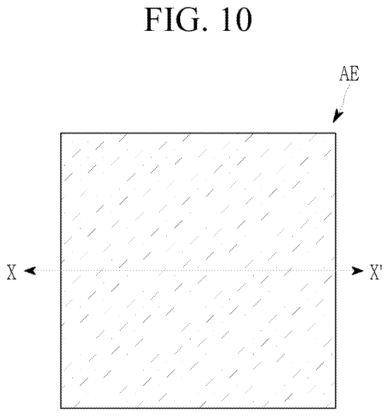

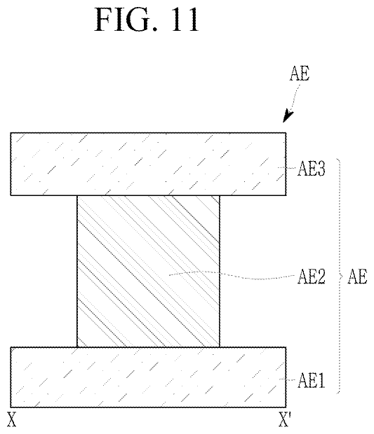

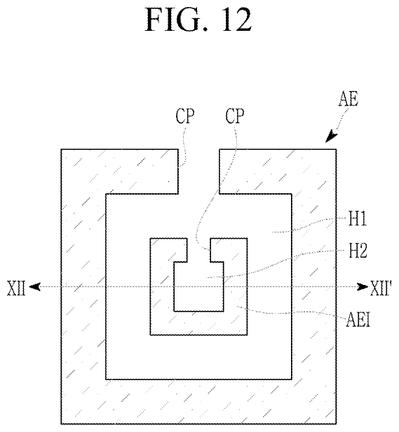

FIG. 10 shows a top surface of an auxiliary electrode AE in which a groove is not formed therein; and FIG. 11 illustrates a cross-section of the auxiliary electrode AE of FIG. 10, taken along the line X-X′. FIG. 12 illustrates a top surface of an auxiliary electrode AE including an inner groove; and FIG. 13 illustrates a cross-section of the auxiliary electrode AE of FIG. 12, taken along the line XII-XII′.

Widths of auxiliary electrodes AE of FIG. 10 and FIG. 12 were equally set to 20 μm×20 μm, and a size of an internal electrode AEI positioned between a first groove H1 and a second groove H2 of the auxiliary electrode AE of FIG. 12 was set to 10 μm×10 μm, and the contact area was compared and is shown in Table 1 below.

TABLE 1

| Referred drawing | FIG. 10 | FIG. 12 |
|---|---|---|
| Contact type | Entire top area contact | Side surface contact |
| Contact structure | [symbol] | [symbol] |
| | ↔ | ↔ |
| | 20 μm | 20 μm |
| Contact area (pad | 24 | 60 |
| diameter 20 μm, | | |
| 3,000 Å contact | | |
| reference in Tip) | | |
| Area ratio | 100% | 250% |

As shown in Table 1, when the pad diameter was 20 μm and the contact area in the auxiliary electrode was 3,000 Å, the contact area of the embodiment of FIG. 10 was 24, but the contact area of the embodiment of FIG. 12 was much larger at 60. That is, assuming that the contact area of the embodiment of FIG. 10 is 100%, it was confirmed that the contact area in the case of FIG. 12 was significantly increased by 250%.

As described above, the display device according to an embodiment forms a groove inside the auxiliary electrode AE, and the auxiliary electrode AE and the second electrode 270 additionally contact more in the inner groove, thereby increasing the contact area and effectively reducing the resistance of the second electrode 270.

The structure including the first groove H1 is shown in FIG. 3 and FIG. 4, and the structure including the first groove H1 and the second groove H2 is illustrated in FIG. 12, but the shape of the auxiliary electrode AE and the shape of the inner groove according to embodiments may be varied.

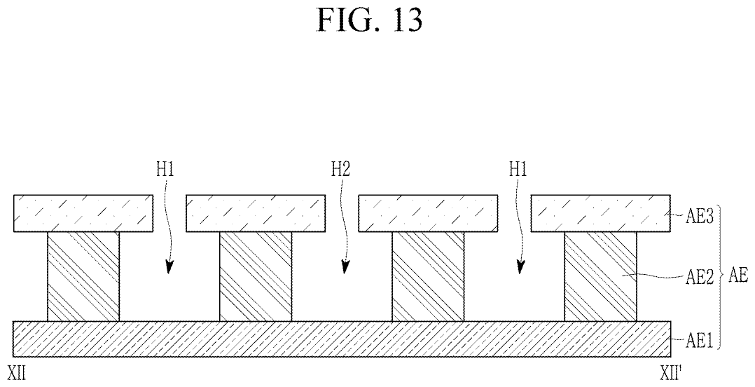

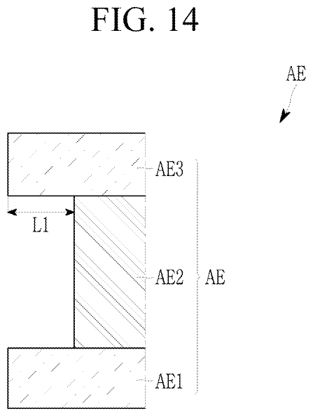

FIG. 14 shows a part of the cross-section of the auxiliary electrode of FIG. 13, illustrating an undercut portion. In an embodiment, a length L1 of the undercut portion of the auxiliary electrode AE may be 0.1 μm to 1 μm. When the length of the undercut is less than 0.1 μm, an area of a region where the second electrode 270 and the auxiliary electrode AE directly contact may be too narrow. In addition, when the undercut length exceeds 1 μm, the second electrode 270 may not be stably deposited on a side of the auxiliary electrode AE.

In an embodiment, a width of the inner groove positioned inside the auxiliary electrode AE may be greater than a height of the auxiliary electrode.

That is, when the width of the groove is smaller than the height of the auxiliary electrode, deposition may not sufficiently occur on the side surface of the auxiliary electrode at an angle.

In an embodiment, the height of the auxiliary electrode may be between 1,000 Å and 20,000 Å. In addition, the width of the inner groove may be 1,000 Å to 20,000 Å.

However, this is an example, and depending on embodiments, the width of the inner groove positioned inside the auxiliary electrode AE may be less than the height of the auxiliary electrode AE. This can be appropriately adjusted according to the contact area of the auxiliary electrode AE and the second electrode 270 desired in each embodiment.

In FIG. 3 and FIG. 4, the structure of the auxiliary electrode AE is multi-layered, but, in an embodiment, the auxiliary electrode AE may be a single layer as long as it includes an undercut structure on the side surface.

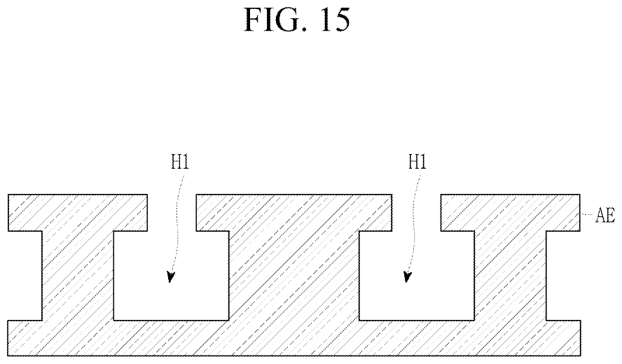

FIG. 15 illustrates a cross-section corresponding to that of FIG. 4, according to another embodiment. Referring to FIG. 15, the auxiliary electrode AE may be a single layer including an undercut structure at a side surface. In this case, the contents of the width of the groove H1 of the auxiliary electrode AE, the length L1 of the undercut, and the like may be the same as described above.

In FIG. 2, the auxiliary electrode AE is shown to be positioned on a same layer as the source electrode SE and the drain electrode DE, but, in an embodiment, the auxiliary electrode AE may be positioned on a same layer as the first electrode 191.

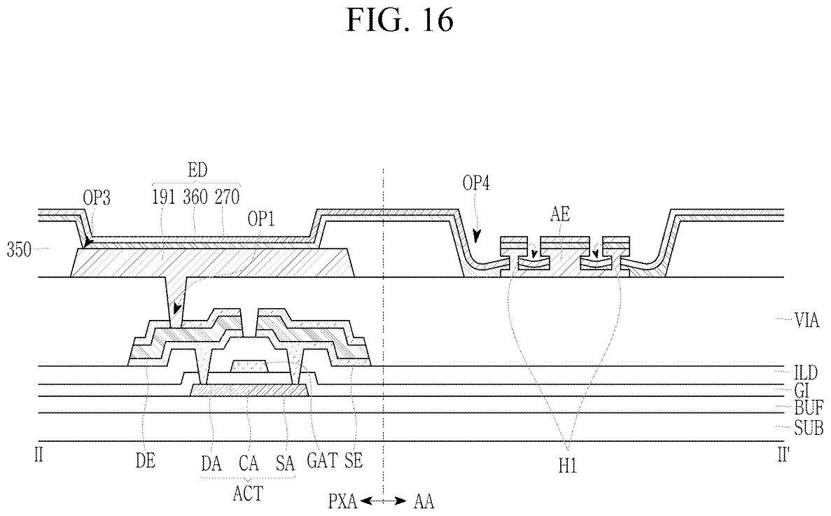

FIG. 16 illustrates a cross-section corresponding to that of FIG. 2, according to another embodiment. The embodiment of FIG. 16 is the same as the embodiment of FIG. 2, except that an auxiliary electrode AE is positioned on the same layer as the first electrode 191. Further detailed descriptions of the same constituent elements will be omitted.

Referring to FIG. 16, an auxiliary electrode region AA will be mainly described. Unlike the embodiment of FIG. 2, in the embodiment of FIG. 16, a second opening OP2 is not positioned in an insulating layer VIA. An auxiliary electrode AE is positioned on the insulating layer VIA, and may be positioned on a same layer as the first electrode 191. In an embodiment, the auxiliary electrode AE is formed by a same process as the first electrode 191 and may contain a same material.

The auxiliary electrode AE includes an undercut structure, and a light emitting element layer 360 and a second electrode 270 are positioned on the auxiliary electrode AE. As previously shown in FIG. 2, the light emitting element layer 360 is positioned on a side of the auxiliary electrode AE, and the second electrode 270 is positioned on the light emitting element layer 360. As shown in FIG. 6, the second electrode 270 directly contacts the side of the auxiliary electrode AE.

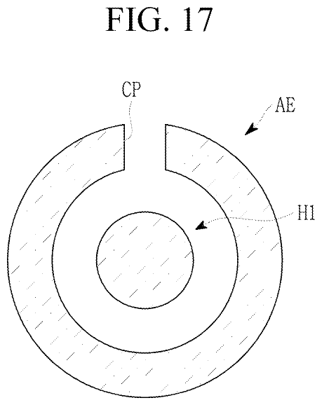

In an embodiment, the auxiliary electrode AE may have a quadrangle shape, but the shape of the auxiliary electrode AE may be varied, such as a polygon and a circle, and the shape of the groove H1 inside the auxiliary electrode AE may also be varied, such as a polygon, a circle, a straight line, and the like. FIG. 17 to FIG. 31 illustrate shapes of auxiliary electrodes AE according to various embodiments. However, FIG. 17 to FIG. 31 are merely examples and are not restrictive. The embodiments of FIG. 17 to FIG. 31 include a cut-off portion CP as in the embodiment of FIG. 5, and the second electrode 270 contacting the auxiliary electrode AE on the inside of the groove H1 and the second electrode 270 contacting the auxiliary electrode AE on the outside of the groove H1 may be connected to each other through the cut-off portion CP.

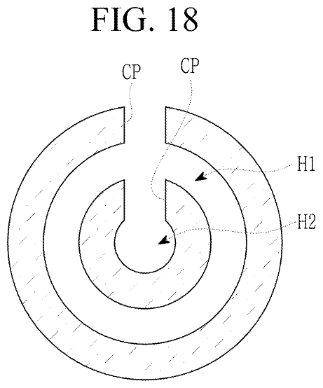

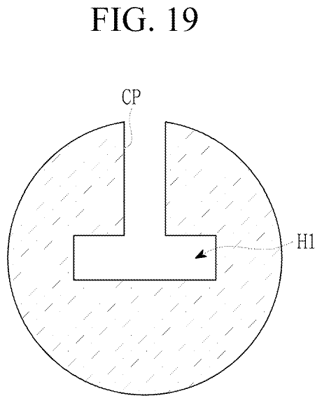

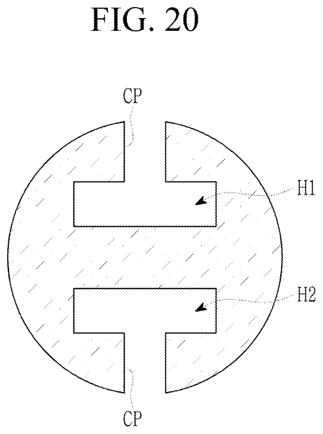

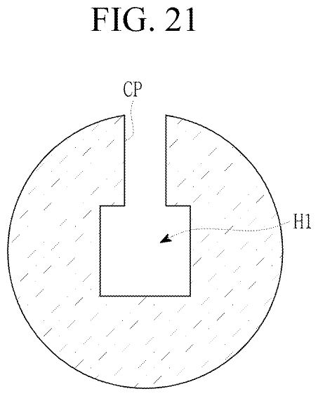

Referring to FIG. 17 to FIG. 21, the auxiliary electrode AE may have a circular shape. In addition, the first groove H1 may have a circular shape. As shown in FIG. 18, a circular-shaped second groove H2 may be positioned within the circular-shaped first groove H1. In another embodiment, as shown in FIG. 19, the first groove H1 may have a straight line shape, and, as shown in FIG. 20, a plurality of grooves H1 and H2 may be included. In another embodiment, as shown in FIG. 21, the first groove H1 may have a shape of a quadrangle. FIG. 21 shows a structure in which the first groove H1 is a quadrangle, but the shape may be a polygon of another type.

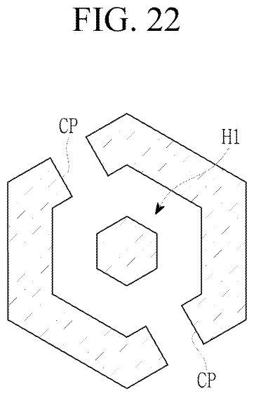

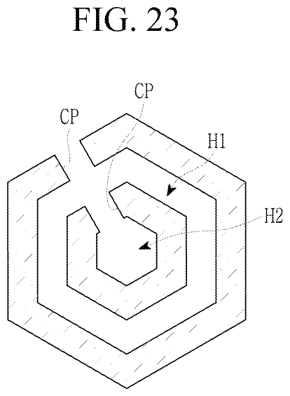

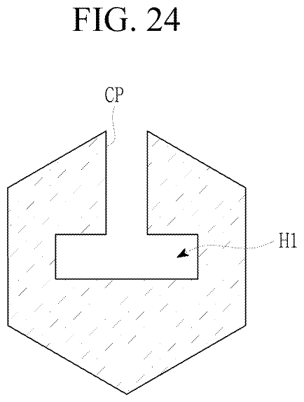

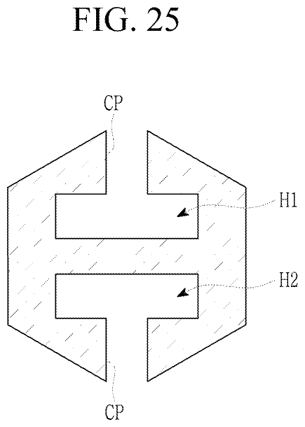

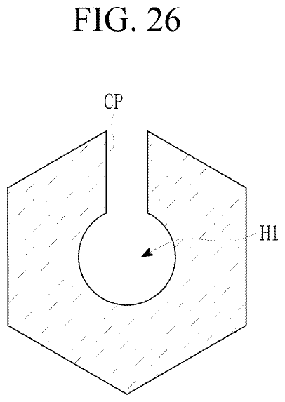

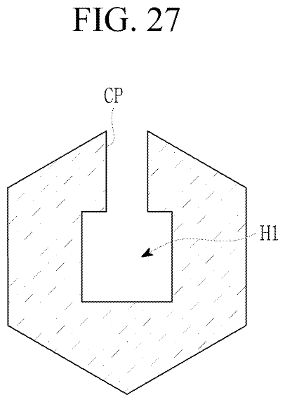

Referring to FIG. 22 to FIG. 27, the auxiliary electrode AE may be hexagonal. In addition, as shown in FIG. 22, the first groove H1 may also have a same hexagonal shape as the auxiliary electrode AE. As shown in FIG. 23, a hexagonal-shaped second groove H2 may be positioned within the hexagonal-shaped first groove H1. As shown in FIG. 24, the first groove H1 may have a straight line shape, and, as shown in FIG. 25, a plurality of grooves H1 and H2 may be included. In another embodiment, as shown in FIG. 26, the first groove H1 may be circular, and, as shown in FIG. 27, the first groove H1 may have a shape of a quadrangle.

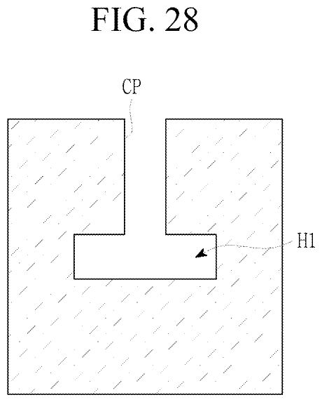

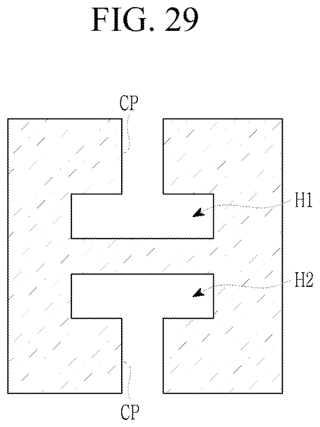

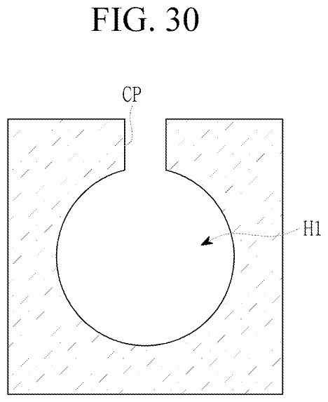

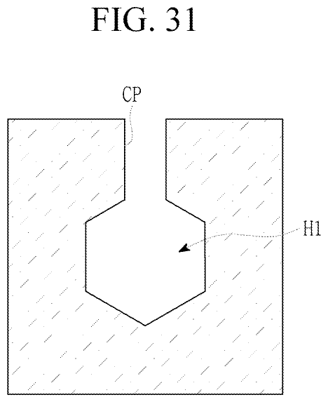

Referring to FIG. 3, FIG. 12, and FIG. 28 to FIG. 31, the auxiliary electrode AE may be quadrangular. As previously shown in FIG. 3, the first groove H1 may also have a same rectangular shape as the auxiliary electrode AE. In addition, as previously as shown in FIG. 12, the second groove H2 may be positioned within the quadrangular-shaped first groove H1. Referring to FIG. 28, the first groove H1 may have a straight line shape, and, referring to FIG. 29, a plurality of grooves H1 and H2 may be included. In another embodiment, as shown in FIG. 30, the first groove H1 may be circular, and, as shown in FIG. 31, the first groove H1 may be hexagonal.

While the present invention has been described in connection with what are presently considered to be some practical embodiments, it is to be understood that the invention is not limited to the disclosed embodiments. On the contrary, it is intended to cover various modifications and equivalent arrangements included within the spirit and scope of the appended claims.

What is claimed is:

1. A display device comprising:
a substrate;
a semiconductor layer on the substrate;
a source electrode and a drain electrode on the semiconductor layer;
an auxiliary electrode on a same layer as the source electrode and the drain electrode;
a first electrode electrically connected with the source electrode or the drain electrode;
a light emitting element layer on the first electrode; and
a second electrode on the light emitting element layer,
wherein the auxiliary electrode comprises at least one groove located inside the auxiliary electrode.

2. The display device of claim 1, wherein
the light emitting element layer and the second electrode are located in the groove of the auxiliary electrode, and
the second electrode directly contacts a side surface of the second electrode in the groove of the auxiliary electrode.

3. The display device of claim 1, wherein
the auxiliary electrode has an undercut structure in which a side surface is positioned inside a top surface,
the light emitting element layer is in direct contact with the auxiliary electrode on the side surface of the auxiliary electrode, and
a part of the second electrode and the auxiliary electrode directly contact on the side surface of the auxiliary electrode.

4. The display device of claim 3, wherein a region where the second electrode and the auxiliary electrode directly contact is farther from the substrate than a region where the light emitting element layer and the auxiliary electrode directly contact.

5. The display device of claim 1, wherein
the auxiliary electrode comprises a first layer, a second layer, and a third layer, and
a planar area of the second layer is narrower than planar areas of the first layer and the third layer.

6. The display device of claim 1, wherein a width of a groove of the at least one groove of the auxiliary electrode is wider than a thickness of the auxiliary electrode.

7. The display device of claim 1, wherein a width of a groove of the at least one groove of the auxiliary electrode is 1,000 Å to 20,000 Å.

8. The display device of claim 1, wherein a planar shape of the auxiliary electrode is polygonal or circular.

9. The display device of claim 1, wherein a planar shape of a groove of the at least one groove is linear, polygonal, or circular.

10. The display device of claim 1, wherein a planar shape of the auxiliary electrode and a planar shape of a groove of the at least one groove are the same.

11. A display device comprising:
a substrate;
a semiconductor layer on the substrate;
a source electrode and a drain electrode on the semiconductor layer;
a first electrode electrically connected with the source electrode or the drain electrode;
a light emitting element layer on the first electrode;
a second electrode on the light emitting element layer; and
an auxiliary electrode on a same layer as the first electrode,
wherein the auxiliary electrode comprises at least one groove located inside the auxiliary electrode.

12. The display device of claim 11, wherein
the light emitting element layer and the second electrode are located in the groove of the auxiliary electrode, and
the second electrode directly contacts a side surface of the auxiliary electrode in the groove of the auxiliary electrode.

13. The display device of claim 11, wherein
the auxiliary electrode has an undercut structure in which a side surface is positioned inside a top surface,
the light emitting element layer is in direct contact with the auxiliary electrode on the side surface of the auxiliary electrode, and
a part of the second electrode ad the auxiliary electrode directly contacts the side surface of the auxiliary electrode.

14. The display device of claim 13, wherein a region where the second electrode and the auxiliary electrode directly contact is farther from the substrate than a region where the light emitting element layer and the auxiliary electrode directly contact.

15. The display device of claim 11, wherein a width of a groove of the at least one groove of the auxiliary electrode is wider than a thickness of the auxiliary electrode.

16. The display device of claim 11, wherein a width of a groove of the at least one groove of the auxiliary electrode is 1,000 Å to 20,000 Å.

17. The display device of claim 11, wherein a planar shape of the auxiliary electrode is polygonal or circular.

18. The display device of claim 11, wherein a planar shape of a groove of the at least one groove is linear, polygonal, or circular.

19. The display device of claim 11, wherein a planar shape of the auxiliary electrode and a planar shape of a groove of the at least one groove are the same.

20. A manufacturing method of a display device, the manufacturing method comprising:
forming a semiconductor layer on a substrate;
forming a source electrode and a drain electrode that are electrically connected with the semiconductor layer;
forming a first electrode that is electrically connected with the source electrode or the drain electrode; and
forming an auxiliary electrode on a same layer as the source electrode and the drain electrode or on a same layer as the first electrode,
wherein the auxiliary electrode comprises one or more grooves.

21. The manufacturing method of the display device of claim 20, further comprising forming a light emitting element layer on the first electrode,
wherein the light emitting element layer is deposited at a first angle with respect to a top surface of the auxiliary electrode.

22. The manufacturing method of the display device of claim 21, further comprising
forming a second electrode on the light emitting element layer,
wherein the second electrode is deposited at a second angle with respect to the top surface of the auxiliary electrode, and
the second angle is smaller than the first angle.

23. The manufacturing method of the display device of claim 22, wherein, in the forming of the second electrode on the light emitting element layer, the second electrode directly contacts the auxiliary electrode at a side surface of the auxiliary electrode.

24. The manufacturing method of the display device of claim 23, wherein a region in which the second electrode and the auxiliary electrode directly contact is located farther from the substrate than a region in which the light emitting device layer and the auxiliary electrode directly contact each other.

25. The manufacturing method of the display device of claim 20, further comprising etching the auxiliary electrode to form an undercut structure in which a side surface of the auxiliary electrode is located more inward than a top surface of the auxiliary electrode.
